(19) United States
(12) Patent Application Publication
(10) Pub. No.: US 2023/0005663 A1
(43) Pub. Date: Jan. 5, 2023

(54) STRUCTURAL BODY

(71) Applicant: Murata Manufacturing Co., Ltd., Nagaokakyo-shi (JP)

(72) Inventors: Yasuhiro SHIMIZU, Nagaokakyo-shi (JP); Masaki NAGATA, Nagaokakyo-shi (JP)

(21) Appl. No.: 17/931,585

(22) Filed: Sep. 13, 2022

Related U.S. Application Data
(63) Continuation of application No. PCT/JP2021/004141, filed on Feb. 4, 2021.

(30) Foreign Application Priority Data
May 12, 2020 (JP) 2020-083907

(51) Int. Cl. H01G 4/008; H01G 4/224; H01L 23/522

(52) U.S. Cl. CPC H01G 4/008; H01G 4/224; H01L 23/5223

(57) ABSTRACT

A structural body that includes: a substrate; a plurality of fibrous materials, each of the plurality of fibrous material including a fibrous core material and a covering layer that covers the fibrous core material such that an exposed portion of the fibrous core material is formed at an end portion thereof; and an adhesive layer that bonds the substrate and the end portion of each of the plurality of fibrous materials to each other such that a boundary between the covering layer and the exposed portion is located inside the adhesive layer.

### CROSS REFERENCE TO RELATED APPLICATIONS

The present application is a continuation of International application No. PCT/JP2021/004141, filed Feb. 4, 2021, which claims priority to Japanese Patent Application No. 2020-083907, filed May 12, 2020, the entire contents of each of which are incorporated herein by reference.

### FIELD OF THE INVENTION

The present disclosure relates to a structural body including a fibrous material.

### BACKGROUND OF THE INVENTION

As a structural body using a fibrous material, nanofibers grown on a metal layer are known. Such a structural body has, for example, an insulator layer and a metal layer formed on the surface thereof to form a metal-insulator-metal (MIM) structure, and is used as a MIM capacitor (Patent Document 1).

Patent Document 1: Japanese Patent Application Laid-open No. 2010-506391

### SUMMARY OF THE INVENTION

In the case of the structural body in which the nanofibers are grown on the metal layer as described in Patent Document 1, the contact point between the metal layer and the nanofibers is only the catalyst portion at the starting point of the growth of the nanofibers. That is, the point contact, and therefore the bonding strength between the metal layer and the nanofibers is not sufficient.

An object of the present disclosure is to provide a structural body in which a fibrous material is disposed on a substrate, the structural body having high bonding strength between the substrate and the fibrous material.

The present disclosure includes the following aspects:

[1] A structural body including: a substrate; a plurality of fibrous materials, each of the plurality of fibrous material including a fibrous core material and a covering layer that covers the fibrous core material such that an exposed portion of the fibrous core material is formed at an end portion thereof; and an adhesive layer that bonds the substrate and the end portion of each of the plurality of fibrous materials to each other such that a boundary between the covering layer and the exposed portion is located inside the adhesive layer.

[2] The structural body according to the above item [1], in which the plurality of fibrous materials are in contact with each other in the adhesive layer.

[3] The structural body according to the above item [1] or [2], in which the plurality of fibrous materials are entangled with each other in the adhesive layer.

[4] The structural body according to any one of the above items [1] to [3], in which at least one of the fibrous core material, the covering layer, and the adhesive layer are conductive.

[5] The structural body according to any one of the above items [1] to [4], in which the fibrous core material and the adhesive layer are conductive.

[6] The structural body according to any one of the above items [1] to [5], in which the covering layer is a first covering layer, and the structural body further comprises a second covering layer covering at least a part of the first covering layer.

[7] The structural body according to any one of the above items [1] to [6], in which the fibrous core material is a carbon nanotube.

[8] A capacitor structural body including a structural body, the structural body including: a substrate; a plurality of fibrous materials, each of the plurality of fibrous materials including a fibrous core material made of a conductor, a first covering layer made of a dielectric covering a surface of the fibrous core material so that an exposed portion of the fibrous core material is formed at the end portion thereof, and a second covering layer made of a conductor covering the first covering layer and electrically insulated from the fibrous core material; and an adhesive layer made of a conductor that bonds the substrate and the end portion of each of the plurality of fibrous materials to each other such that a boundary between the first covering layer and the exposed portion is located inside the adhesive layer.

[9] The capacitor structural body according to the above item [8], in which the exposed portions of the plurality of fibrous materials are in contact with each other in the adhesive layer.

[10] The capacitor structural body according to the above item [8] or [9], in which the exposed portions are entangled with each other in the adhesive layer.

[11] The capacitor structural body according to any one of the above items [8] to [10], in which the fibrous core material is a nanowire, a nanotube, or a nanofiber.

[12] The capacitor structural body according to any one of the above items [8] to [10], in which the fibrous core material is a carbon nanotube.

According to the present invention, since the fibrous material is bonded to the substrate by the adhesive layer, it is possible to provide a structural body having high bonding strength between the fibrous material and the substrate.

BRIEF EXPLANATION OF THE DRAWINGS

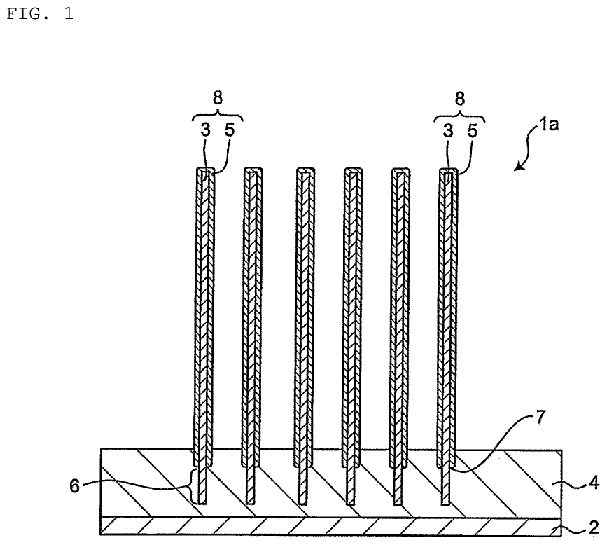

FIG. 1 schematically illustrates a cross section of a structural body la according to an embodiment of the present disclosure.

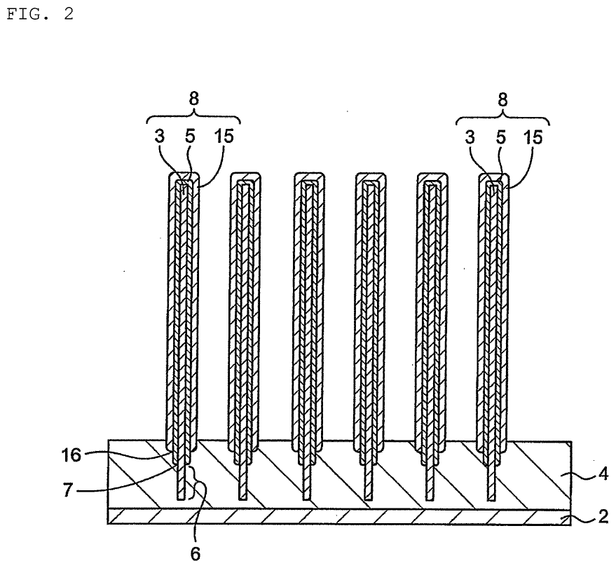

FIG. 2 schematically illustrates a cross section of one modified example of the structural body.

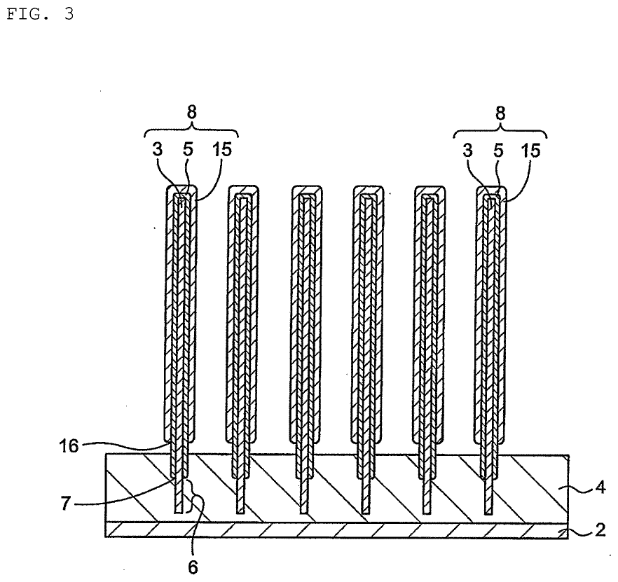

FIG. 3 schematically illustrates a cross section of another modified example of the structural body.

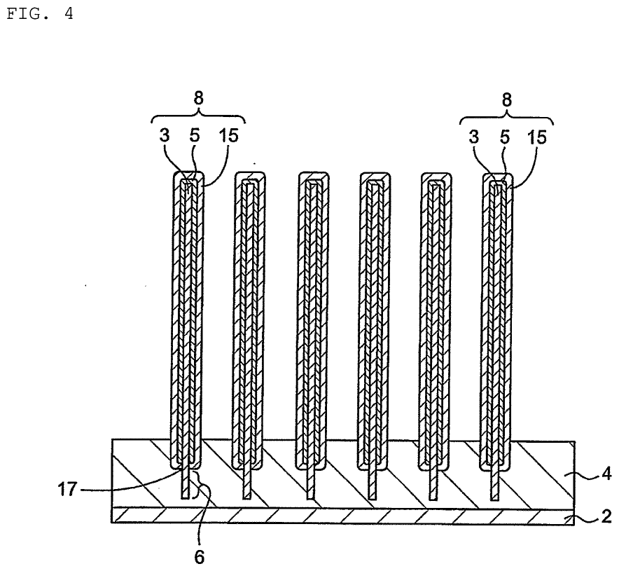

FIG. 4 schematically illustrates a cross section of another modified example of the structural body.

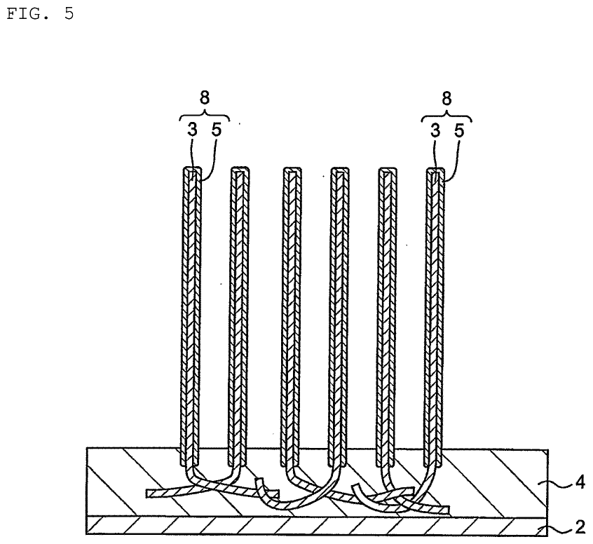

FIG. 5 schematically illustrates a cross section of another modified example of the structural body.

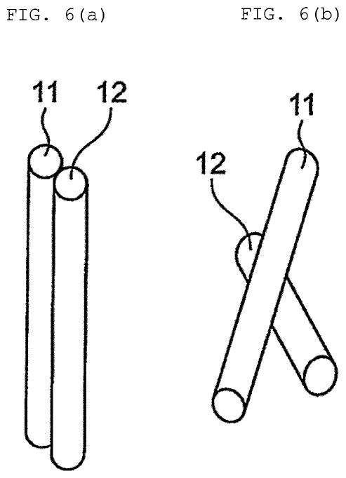

FIGS. 6(a) and 6(b) are views illustrating a state in which two fibrous materials are in contact with each other.

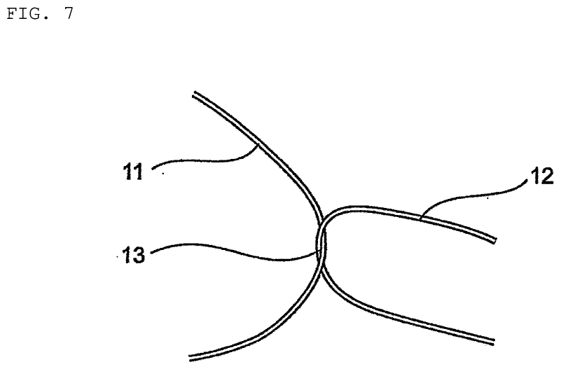

FIG. 7 is a view illustrating a state in which the two fibrous materials are entangled with each other.

### DETAILED DESCRIPTION OF THE INVENTION

Hereinafter, a structural body of the present disclosure will be described in detail with reference to the drawings. However, the shape, arrangement, and the like of the structural body and each component of the present embodiment are not limited to the illustrated example.

### First Embodiment

FIG. 1 illustrates a cross section of a structural body 1a according to an embodiment of the present disclosure. As illustrated in FIG. 1, the structural body la includes a substrate 2, a plurality of fibrous materials 8 in which a fibrous core material 3 is coated with a covering layer 5, and an adhesive layer 4 for bonding the substrate 2 and one end portion of the fibrous material 8. The fibrous core material 3 is covered with the covering layer 5 such that an exposed portion 6 exists at the one end portion thereof. The fibrous material 8 is bonded to the substrate 2 with the adhesive layer 4 interposed therebetween. A boundary 7 between the covering layer 5 and the exposed portion 6 of the fibrous material 8 is located inside the adhesive layer 4.

The material constituting the substrate 2 is not particularly limited, but may be, for example, a conductive material such as copper or aluminum, or an insulating material such as ceramic or resin. The material constituting the substrate 2 may be one kind or two or more kinds. For example, a conductive material may be disposed on an insulating material.

The shape of the substrate 2 is not particularly limited, but typically may be a block shape, a plate shape, a film shape, a foil shape, or the like. Preferably, the shape of the substrate 2 is a shape having a flat surface.

In one aspect, the substrate 2 is formed of a conductive material.

In one aspect, the substrate 2 may have a metal layer formed on a surface of a support material of an insulating material. The metal layer can be formed by, for example, atomic layer deposition (ALD), sputtering, coating, plating, or the like.

In the above aspect, the metal layer on the substrate 2 may be an electrode or a wiring.

When the structural body of the present disclosure is used as a material of an electronic component, for example, a capacitor or the like, it is preferable that the substrate 2 is made of a conductive material or the surface of the substrate 2 is made conductive as described above because it is easy to take contact as an electrode, the resistance value is low, and the heat resistance is high.

In one aspect, the surface of the substrate 2 is roughened. By roughening the surface of the substrate, the bonding strength between the substrate 2 and the adhesive layer 4 can be further increased.

The fibrous material 8 includes a fibrous core material 3 and a covering layer 5.

The fibrous core material 3 is not particularly limited as long as it has an elongated thread shape, and examples thereof include a nanotube, a nanowire, and a nanofiber.

The nanotube is not particularly limited, and examples thereof include metal-based nanotubes, organic nanotubes, and inorganic nanotubes. Typically, the nanotube may be a carbon nanotube or a titania carbon nanotube.

The nanowire is not particularly limited, and examples thereof include silicon nanowires and silver nanowires.

The nanofiber is not particularly limited, and examples thereof include a carbon nanofiber and a cellulose nanofiber.

In a preferred aspect, the fibrous core material 3 is a conductive fibrous core material. By using the conductive fibrous core material, the electrical resistance between the fibrous material 8 and the substrate 2 can be reduced.

In a preferred aspect, the fibrous core material 3 is a carbon nanotube.

The chirality of the carbon nanotube is not particularly limited, and may be either a semiconductor type or a metal type, or a mixture thereof may be used. From the viewpoint of reducing the resistance value, it is preferable that the ratio of the metal type is high.

The number of layers of the carbon nanotube is not particularly limited, and may be either a single-wall carbon nanotube (SWCNT) having one layer or a multiwall carbon nanotube (MWCNT) having two or more layers.

The method for producing the carbon nanotube is not particularly limited, and chemical vapor deposition (CVD), plasma enhanced CVD, or the like can be used. In this case, as the catalyst, iron, nickel, platinum, cobalt, an alloy containing these, or the like is used. The material of a substrate to which the catalyst is applied is not particularly limited, and for example, silicon oxide, silicon, gallium arsenide, aluminum, SUS, or the like can be used. As a method for applying the catalyst to the substrate, a method combining CVD, sputtering, physical vapor deposition (PVD), and the like with techniques such as lithography and etching can be used. The gas to be used is not particularly limited, and for example, carbon monoxide, methane, ethylene, acetylene, a mixture of these with hydrogen or ammonia, or the like can be used. The end of the carbon nanotube on the catalyst application side on the substrate is a fixed end, and the other end (free end) grows and the length increases. The length and diameter of the carbon nanotube may vary depending on changes in parameters such as gas concentration, gas flow rate, temperature. That is, the length and diameter of the carbon nanotube can be adjusted by appropriately selecting these parameters.

The diameter and length of the fibrous core material 3 are not particularly limited.

The length of the fibrous core material 3 may be, for example, several μm or more, 20 μm or more, 50 μm or more, 100 μm or more, 500 μm or more, 750 μm or more, 1000 μm or more, or 2000 μm or more. The upper limit of the length of the fibrous core material is not particularly limited. The length of the fibrous core material may be, for example, 10 mm or less, 5 mm or less, or 3 mm or less.

The diameter of the fibrous core material 3 may be, for example, 0.1 nm or more, 1 nm or more, or 10 nm or more. The diameter of the fibrous core material 3 may be 1000 nm or less, 800 nm or less, or 600 nm or less.

The fibrous core material 3 may be oriented in the longitudinal direction thereof. For example, in the case of a carbon nanotube, the carbon nanotube can be oriented in the process of growing the carbon nanotube. In addition, the fibrous core material can be oriented in a dispersion.

The fibrous core material 3 is covered with the covering layer 5.

The material constituting the covering layer 5 may be either a conductive material or an insulating material. That is, the covering layer 5 may be a conductor layer or an insulator layer (or a dielectric layer).

The conductive material constituting the conductor layer is not particularly limited, and examples thereof include silver, gold, copper, platinum, aluminum, and an alloy containing these. These may be used alone or in combination of two or more.

The thickness of the conductor layer may be, for example, 3 nm or more, and preferably 10 nm or more. When the thickness of the covering layer is 3 nm or more, the resistance of the covering layer itself can be reduced. The thickness of the conductor layer may be, for example, 500 nm or less, preferably 100 nm or less.

The method for forming the conductor layer is not particularly limited, and CVD, ALD, sputtering, coating, plating, or the like can be used.

In one aspect, the surface of the conductor layer may be insulated. The insulation can be performed by, for example, chemical treatment such as oxidation treatment.

The insulating material constituting the insulator layer is not particularly limited, and examples thereof include silicon dioxide, aluminum oxide, silicon nitride, tantalum oxide, hafnium oxide, barium titanate, and lead zirconate titanate. These may be used alone or in combination of two or more.

The thickness of the insulator layer is preferably 5 nm or more, and more preferably 10 nm or more. By setting the thickness of the insulator layer to 5 nm or more, the insulation property can be enhanced, and the leakage current can be reduced. The thickness of the insulator layer is preferably 100 nm or less, and more preferably 50 nm or less. When the thickness of the insulator layer is 100 nm or less, a larger electrostatic capacitance can be obtained when the insulator layer is used as a dielectric layer of a capacitor.

The method for forming the insulator layer is not particularly limited, and ALD, sputtering, PVD, CVD, a film forming method using a supercritical fluid, or the like can be used.

After the covering layer 5 is deposited on the fibrous core material 3, further treatment such as reduction or oxidation of the deposited film may be performed, or surface treatment may be performed.

In one aspect, at least one of the fibrous core material 3 and the covering layer 5 and the adhesive layer 4 are conductive. With such a configuration, a structural body having high conductivity between the substrate 2 and the fibrous material 8 can be obtained.

In one aspect, the fibrous core material 3, the covering layer 5, and the adhesive layer 4 are conductive. With such a configuration, a structural body having higher conductivity between the substrate 2 and the fibrous material 8 can be obtained.

In FIG. 1, the covering layer is only the covering layer 5, but is not limited thereto, and a plurality of covering layers may be present.

In one aspect, as illustrated in FIGS. 2, 3, and 4, a second covering layer 15 may further be present on the covering layer 5 (hereinafter, also referred to as “first covering layer”). In this aspect, the fibrous material 8 includes the fibrous core material 3, the first covering layer 5, and the second covering layer 15.

In one aspect, as illustrated in FIG. 2, the second covering layer 15 covers a part of the first covering layer 5, and a boundary 16 between the exposed portion of the first covering layer 5 and the second covering layer 15 is located inside the adhesive layer 4. In this aspect, the exposed portion 6, the boundary 7, and the boundary 16 are located in this order from the end on the substrate side. By disposing the boundary 16 inside the adhesive layer 4, peeling of the second covering layer 15 can be suppressed.

In one aspect, as illustrated in FIG. 3, the second covering layer 15 covers a part of the first covering layer 5, and the boundary 16 between the exposed portion of the first covering layer 5 and the second covering layer 15 is located outside the adhesive layer 4 to be separated from the adhesive layer 4. The exposed portion 6 and the boundary 7 are located inside the adhesive layer 4. By disposing the boundary 16 outside the adhesive layer 4, direct conduction can be prevented when the adhesive layer 4 and the second covering layer 15 are conductive, and the fibrous core material 3, the first covering layer 5, and the second covering layer 15 can form a MIM capacitor structure.

In one aspect, as illustrated in FIG. 4, the second covering layer 15 covers the entire first covering layer 5. In this aspect, the boundary between the exposed portion 6 and the covering layer is the boundary 17 between the exposed portion 6 of the fibrous core material 3 and the second covering layer 15. The boundary 17 between the exposed portion 6 and the second covering layer 15 is located inside the adhesive layer 4. By disposing the boundary 17 inside the adhesive layer 4, peeling of the first covering layer 5 and the second covering layer 15 can be suppressed.

Each of the fibrous core material 3, the first covering layer 5, and the second covering layer 15 may be insulative or conductive.

In one aspect, the fibrous core material 3 is conductive, the first covering layer 5 is conductive, and the second covering layer 15 is insulating. With such a configuration, a structural body having high conductivity between the substrate 2 and the fibrous material 8 can be obtained.

In one aspect, the fibrous core material 3 is conductive, the first covering layer 5 is insulating, and the second covering layer 15 is conductive. With such a configuration, the fibrous core material 3, the first covering layer 5, and the second covering layer 15 can form a MIM capacitor structure.

In another aspect, similarly to the second covering layer 15, a plurality of layers such as a third covering layer may be present on the second covering layer, and a fourth covering layer may be present on the third covering layer.

The fibrous material 8 has the exposed portion 6 in which the fibrous core material 3 is exposed from the covering layer 5.

The exposed portion 6 is present at one end of the fibrous material 8. Here, the end portion refers to a region up to a certain distance from the end of the fibrous material, and may be, for example, a region within 100 nm from the end, a region within 500 nm, a region within 1 μm, a region within 10 μm, or a region within 100 μm.

In FIG. 1, only one exposed portion 6 is continuously present from the end of the fibrous material 8, but the present invention is not limited thereto, and a plurality of exposed portions may be present. In this case, there may be a plurality of boundaries between the fibrous material and the covering layer. In a preferred aspect, the plurality of boundaries are all located inside the adhesive layer 4.

The method for forming the exposed portion 6 is not particularly limited. For example, when the covering layer is formed on the fibrous material, a film forming process may be controlled to form the exposed portion, or after the fibrous material is coated with the covering layer, a part of the covering layer may be removed to form the exposed portion. The removal of the covering layer can be performed by gas etching, ion etching, ion beam etching, dry etching such as lapping, wet etching, or mechanical polishing.

The adhesive layer 4 bonds the substrate 2 and the fibrous material 8.

The material constituting the adhesive layer 4 is not particularly limited, and examples thereof include a conductive adhesive and a conductive polymer.

Examples of the conductive adhesive include a conductive material in which a metal filler such as silver, nickel, copper, tin, gold, or palladium or a carbon filler is dispersed in a resin such as an epoxy resin, a polyimide resin, a silicone resin, or a polyurethane resin.

Examples of the conductive adhesive include polypyrrole, polypyrrole derivatives, polyaniline, polyaniline derivatives, polythiophene, and polythiophene derivatives.

The adhesive layer 4 may be any of a paste-like, sheet-like, gel-like, or liquid adhesive. In order to easily introduce the adhesive into the gap between the fibrous materials 8, a liquid or gel-like adhesive or an adhesive that becomes liquid or gel-like at the time of heating is preferable.

The thickness of the adhesive layer may be preferably 1 μm to 100 μm, and more preferably 5 μm to 50 μm.

Bonding between the substrate 2 and the fibrous material 8 is performed by embedding one end of the fibrous material 8 in an adhesive layer.

For example, a method is used in which an adhesive layer is formed of a material whose viscosity is lowered by heating, the fibrous material and the adhesive layer are heated at a high temperature while being pressurized in the directions of the fibrous material and the adhesive layer, an end portion where an exposed portion of the fibrous material is present is press-fitted into the adhesive layer, and then the adhesive layer is cooled to normal temperature to cure the adhesive layer.

The fibrous material 8 and the substrate 2 may or may not be in contact with each other. In one aspect, a part of the fibrous material 8 may be located inside the substrate 2, for example, in a state where the end of the fibrous material 8 is inserted into the substrate 2. By inserting the fibrous material 8 into the substrate 2, an anchor effect is obtained, and the bonding strength between the fibrous material 8 and the adhesive layer 4 and the bonding strength between the fibrous material 8 and the substrate 2 are improved.

In one aspect, as illustrated in FIG. 5, a plurality of fibrous materials 8 may be in contact with each other inside the adhesive layer 4. When the plurality of fibrous materials 8 are in contact with each other, the fibrous materials 8 are less likely to be detached from the adhesive layer 4, and the bonding strength is further improved.

The contact of the fibrous material 8 may be linear contact (FIG. 6(a)) or point contact (FIG. 6(b)). In addition, although not illustrated, in a case where the fibrous material has a flat surface, the surface contact may be performed. Since the bonding strength is increased, it is preferable that the contact area is larger. For example, line contact is preferable to point contact.

In a preferred aspect, the fibrous materials 8 are in contact with each other in the exposed portion 6. By bringing the fibrous materials 8 into contact with each other in the exposed portion 6, in other words, by bringing the fibrous core materials 3 of the fibrous materials 8 into contact with each other, when the structural body of the present disclosure is used as one element of an electronic component, a resistance value between the fibrous materials can be reduced.

In a preferred aspect, the fibrous material 8 has a plurality of contacts with other fibrous materials. By providing the plurality of contacts, the bonding strength is further improved, and the resistance value is further reduced.

In a preferred aspect, the fibrous materials 8 are entangled with each other in the adhesive layer 4. When the fibrous materials are entangled with each other, the bonding strength is further improved. Here, the term “entangled” refers to a state as illustrated in FIG. 7, that is, a state in which a plurality of fibrous materials (a fibrous material 11 and a fibrous material 12 in FIG. 7) are in contact with each other in a certain region instead of a point, and in the contact region 13, axes of the two fibrous materials are directed in different directions from each other, typically, a state in which at least one of the fibrous materials is wound around a surface of the other fibrous material.

In the structural body of the present disclosure, the exposed portion 6 of the bonded fibrous core material 3 and the boundary 7 between the exposed portion 6 and the covering layer 5 are located inside the adhesive layer 4. In other words, a part of the covering layer 5 is located inside the adhesive layer. In the structural body as described in Patent Document 1, since the fibrous material 8 is bonded to the substrate at a point, the bonding strength is relatively low. However, in the structural body of the present disclosure, by disposing the boundary 7 between the exposed portion 6 and the covering layer 5 inside the adhesive layer 4, the bonding strength between the fibrous material 8 and the substrate 2 is improved, and further, peeling of the covering layer 5 can be suppressed.

The structural body of the present disclosure can be used in electronic components such as capacitors and sensors, heat dissipation components, and the like.

Although the structural body of the present disclosure has been described above, the structural body of the present disclosure is not limited thereto. For example, the configurations described above may be combined.

The present disclosure provides a capacitor structural body including the structural body of the present disclosure. That is, the capacitor structural body of the present disclosure may include the features of the structural body of the present disclosure described above.

A capacitor structural body of the present disclosure includes a structural body including: a substrate; a plurality of fibrous materials, each of the plurality of fibrous materials including a fibrous core material made of a conductor, a first covering layer made of a dielectric covering a surface of the fibrous core material so that an exposed portion of the fibrous core material is formed at the end portion thereof, and a second covering layer made of a conductor covering the first covering layer and electrically insulated from the fibrous core material; and an adhesive layer made of a conductor that bonds the substrate and the end portion of each of the plurality of fibrous materials to each other such that a boundary between the first covering layer and the exposed portion is located inside the adhesive layer.

The capacitor structural body of the present disclosure may have a structure as illustrated in FIG. 3.

When the capacitor structural body of the present disclosure has the structure illustrated in FIG. 3, the fibrous core material 3 is preferably a conductor, the first covering layer 5 is preferably a dielectric, the second covering layer 15 is preferably a conductor, and the fibrous core material 3, the first covering layer 5, and the second covering layer 15 constitute a MIM structure. That is, the fibrous core material 3 functions as a lower electrode, the first covering layer 5 functions as a dielectric layer, and the second covering layer 15 functions as an upper electrode. The adhesive layer 4 is a conductor, and at least a part of the surface of the substrate 2 is a conductor. The fibrous core material 3 as the lower electrode is electrically drawn out to the outside by the adhesive layer 4 and the substrate 2.

In the case of a structure in which carbon nanotubes are grown directly on a substrate as in Patent Document 1, the carbon nanotubes and the substrate are in point contact, and the resistance value increases. In the capacitor structural body of the present disclosure, since the fibrous core material 3 is in contact with the conductive adhesive layer 4 at the exposed portion 6, the contact area increases and the resistance decreases between the fibrous core material 3 and the adhesive layer 4, and the resistance value between the fibrous core material 3 and the substrate 2 also decreases.

Although the capacitor structural body of the present disclosure has been described above, the capacitor structural body of the present disclosure is not limited thereto. For example, the configurations described above may be combined.

For example, in one aspect, in the capacitor structural body similar to the structural body illustrated in FIG. 5, the exposed portions of the plurality of fibrous materials may be in contact with each other, preferably entangled with each other, in the adhesive layer. By bringing the plurality of fibrous materials into contact with or entangled with each other, the bonding strength can be improved, and the resistance value of the capacitor can be reduced.

In one aspect, the fibrous core material may be a nanowire, a nanotube, or a nanofiber, preferably a carbon nanotube. By using the fibrous core material having a nanostructure, the specific surface area can be increased, and the electrostatic capacitance can be increased. Furthermore, by using the carbon nanotube, the resistance value of the capacitor can be reduced in addition to the above effects.

The structural body of the present disclosure can be suitably used for various applications such as a capacitor.

### DESCRIPTION OF REFERENCE SYMBOLS

1a: Structural body

2: Substrate

3: Fibrous core material

4: Adhesive layer

5: Covering layer

6: Exposed portion

7: Boundary

8: Fibrous material

11: Fibrous material

12: Fibrous material

13: Contact region

15: Second covering layer

16: Boundary

17: Boundary

1. A structural body comprising:
a substrate;
a plurality of fibrous materials, each of the plurality of fibrous material including a fibrous core material and a covering layer that covers the fibrous core material such that an exposed portion of the fibrous core material is formed at an end portion thereof; and
an adhesive layer that bonds the substrate and the end portion of each of the plurality of fibrous material to each other such that a boundary between the covering layer and the exposed portion is located inside the adhesive layer.

2. The structural body according to claim 1, wherein the plurality of fibrous materials are in contact with each other in the adhesive layer.

3. The structural body according to claim 2, wherein the plurality of fibrous materials are entangled with each other in the adhesive layer.

4. The structural body according to claim 1, wherein the plurality of fibrous materials are entangled with each other in the adhesive layer.

5. The structural body according to claim 1, wherein at least one of the fibrous core material, the covering layer, and the adhesive layer are conductive.

6. The structural body according to claim 1, wherein the fibrous core material and the adhesive layer are conductive.

7. The structural body according to claim 1, wherein the fibrous core material, the covering layer, and the adhesive layer are conductive.

8. The structural body according to claim 1, wherein the covering layer is a first covering layer, and the structural body further comprises a second covering layer covering at least a part of the first covering layer.

9. The structural body according to claim 8, wherein a boundary between an exposed portion of the first covering layer and the second covering layer is located inside the adhesive layer.

10. The structural body according to claim 8, wherein a boundary between an exposed portion of the first covering layer and the second covering layer is located outside the adhesive layer.

11. The structural body according to claim 8, wherein the second covering layer covers the entire first covering layer.

12. The structural body according to claim 1, wherein the fibrous core material is a carbon nanotube.

13. A capacitor structural body comprising a structural body, the structural body including:
a substrate;
a plurality of fibrous materials, each of the plurality of fibrous materials including a fibrous core material made of a conductor, a first covering layer made of a dielectric covering a surface of the fibrous core material so that an exposed portion of the fibrous core material is formed at the end portion thereof, and a second covering layer made of a conductor covering the first covering layer and electrically insulated from the fibrous core material; and
an adhesive layer made of a conductor that bonds the substrate and the end portion of each of the plurality of fibrous materials to each other such that a boundary between the first covering layer and the exposed portion is located inside the adhesive layer.

14. The capacitor structural body according to claim 13, wherein the exposed portions of the plurality of fibrous materials are in contact with each other in the adhesive layer.

15. The capacitor structural body according to claim 14, wherein the exposed portions are entangled with each other in the adhesive layer.

16. The capacitor structural body according to claim 13, wherein the exposed portions are entangled with each other in the adhesive layer.

17. The capacitor structural body according to claim 13, wherein the fibrous core material is a nanowire, a nanotube, or a nanofiber.

18. The capacitor structural body according to claim 13, wherein the fibrous core material is a carbon nanotube.

19. The capacitor structural body according to claim 13, wherein a boundary between an exposed portion of the first covering layer and the second covering layer is located inside the adhesive layer.

20. The capacitor structural body according to claim 13, wherein a boundary between an exposed portion of the first covering layer and the second covering layer is located outside the adhesive layer.
